(19) United States
(12) Patent Application Publication
(10) Pub. No.: US 2026/0144102 A1
(43) Pub. Date: May 21, 2026

(54) SEMICONDUCTOR PACKAGE

(71) Applicant: Samsung Electronics Co., Ltd., Suwon-si (KR)

(72) Inventor: Young-Ja KIM, Suwon-si (KR)

(21) Appl. No.: 19/197,086

(22) Filed: May 2, 2025

(30) Foreign Application Priority Data
Nov. 15, 2024 (KR) 10-2024-0163320

(51) Int. Cl. H01L 23/498; H01L 21/48; H01L 21/56; H01L 23/00; H01L 23/31; H01L 23/538; H01L 25/065; H10B 80/00; H10D 80/30

(52) U.S. Cl. CPC H10W 70/65; H10W 70/093; H10W 70/611; H10W 74/016; H10W 74/114; H10W 90/00; H10B 80/00; H10D 80/30; H10W 72/01235; H10W 72/01255; H10W 72/0198; H10W 72/227; H10W 72/856; H10W 72/877; H10W 74/10; H10W 90/24; H10W 90/401; H10W 90/724; H10W 90/732

(57) ABSTRACT

A semiconductor package includes a package substrate, a first structure including a first chip on the package substrate, a first wiring post connected to the first chip, and a first molding layer surrounding the first chip and the first wiring post, and a second structure including a second chip on the package substrate, a second wiring post connected to the second chip, and a second molding layer surrounding the second chip and the second wiring post. The second structure includes a block in a portion of an area over the package substrate and including a first molding portion surrounding the second chip and the second wiring post, a second molding portion in a remaining area over the package substrate, and a boundary portion positioned between the second molding portion and a block surface located at a lateral side of the first molding portion facing the second molding portion.

### CROSS-REFERENCE TO RELATED APPLICATIONS

This application claims the benefit of Korean Patent Application No. 10-2024-0163320, filed on Nov. 15, 2024, in the Korean Intellectual Property Office, the disclosure of which is incorporated herein by reference for all purposes in its entirety.

### FIELD

The present disclosure relates to a semiconductor package.

### BACKGROUND

Due to advancements in the electronics industry, demands for high functionality, high speed, and miniaturization of electronic components are increasing. In response, a method of stacking and mounting multiple semiconductor chips on one package wiring structure or a method of stacking a package on another package may be used. For example, a package-in-package (PIP) type of semiconductor package or a package-on-package (POP) type of semiconductor package may be used.

Meanwhile, the high integration of semiconductor packages may lead to using a vertical wiring structure, in which semiconductor chips are stacked vertically and the semiconductor chips are electrically connected, or the like.

### SUMMARY

An embodiment of the present disclosure of the present disclosure provides a semiconductor package of which a manufacturing process is simplified.

Another embodiment of the present disclosure of the present disclosure provides a semiconductor package in which warpage is suppressed.

The present disclosure is not limited to the technical features described above, and other unstated technical features may be made apparent to those skilled in the art from the following description.

According to an embodiment of the present disclosure, there is provided a semiconductor package including a package substrate, a first structure including a first chip on the package substrate, a first wiring post connected to the first chip, and a first molding layer surrounding the first chip and the first wiring post, and a second structure including a second chip on the package substrate, a second wiring post connected to the second chip, and a second molding layer surrounding the second chip and the second wiring post, and the second structure may include a block in a portion of a first area overlapping the package substrate and including a first molding portion surrounding the second chip and the second wiring post, a second molding portion formed in a second area adjacent the first area overlapping the package substrate, and a boundary portion positioned between the second molding portion and a block surface located at a lateral side of the first molding portion facing the second molding portion.

According to another embodiment of the present disclosure, there is provided a semiconductor package including a package substrate, a first structure including a first chip on the package substrate, a first wiring post connected to the first chip, and a first molding layer surrounding the first chip and the first wiring post, and a second structure including a second chip on the package substrate, a second wiring post connected to the second chip, and a second molding layer surrounding the second chip and the second wiring post, and the second structure may include a first molding portion comprising a first portion of the second molding layer, surrounding the second chip and the second wiring post, and having a first degree of hardness, a second molding portion comprising a second portion separate from the first portion of the second molding layer and having a second degree of hardness different from the first degree of hardness, and a boundary portion positioned between the first molding portion and the second molding portion and having a third degree of hardness that is a value between the first degree of hardness and the second degree of hardness.

According to another embodiment of the present disclosure, there is provided a method of manufacturing a semiconductor package, the method including stacking a plurality of chips spaced apart from each other on a base, disposing a plurality of wiring posts corresponding to each of the plurality of chips, forming a molding layer to surround the plurality of chips and the plurality of wiring posts, cutting a block including at least one of the plurality of chips, at least one of the plurality of wiring posts, and at least a portion of the molding layer from the base, and stacking the block overlapping a package substrate.

Details of example embodiments are included in the detailed description and drawings.

### BRIEF DESCRIPTION OF THE FIGURES

These and/or other features and advantages of the present disclosure will become apparent and more readily appreciated from the following description of example embodiments, taken in conjunction with the accompanying drawings of which:

FIG. 1 is a diagram illustrating a semiconductor package according to some example embodiments;

FIG. 2 is a diagram illustrating a semiconductor package according to some example embodiments;

FIGS. 3 to 19 are diagrams of intermediate operations illustrating a method of manufacturing a semiconductor package according to some example embodiments;

FIG. 20 is a diagram illustrating a semiconductor package according to another example embodiment;

FIG. 21 is a diagram illustrating a semiconductor package according to another example embodiment; and

FIGS. 22 to 25 are diagrams of intermediate operations illustrating a method of manufacturing a semiconductor package according to another example embodiment.

### DETAILED DESCRIPTION

Before describing example embodiments in detail, the words and terminologies used in the specification and claims are not to be construed as limited to common or dictionary meanings but construed as meanings and concepts coinciding with the technical idea of the present disclosure under the principle that the inventor(s) may appropriately define the concept of the terms to explain his or her own invention in the best manner. Therefore, the example embodiments described in the specification and the configurations illustrated in the drawings are no more than the example embodiments of the present disclosure and do not fully cover the technical idea of the present disclosure. Accordingly, it should be understood that there may be various equivalents and modification examples that may replace those when this application is filed.

In the following description, a singular expression includes a plural expression unless apparently otherwise defined by context. It should be understood that terms such as “comprise or include” and “composed of” are intended to indicate the presence of a feature, a number, a step, an operation, an element, a component, or a combination thereof described in the specification and not intended to exclude the possibility of the presence or addition of one or more other features, numbers, steps, operations, elements, components, or combinations thereof in advance.

In the present disclosure, a singular expression includes a plural expression unless apparently otherwise defined by context. In addition, although the terms such as first and second may be used to describe various elements, these elements are not limited by the above terms, and the terms may be used to distinguish one element from another. Within the scope of the present disclosure, a first element may be referred to as a second element, and similarly, a second element may be referred to as a first element. Further, in the accompanying drawings, the shapes, sizes, and the like of elements may be exaggerated for clearer description.

It will be understood that spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly. The shapes, sizes, and the like of elements may be exaggerated in the drawings for clearer description.

The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

Hereinafter, example embodiments of the present disclosure will be described with reference to the accompanying drawings.

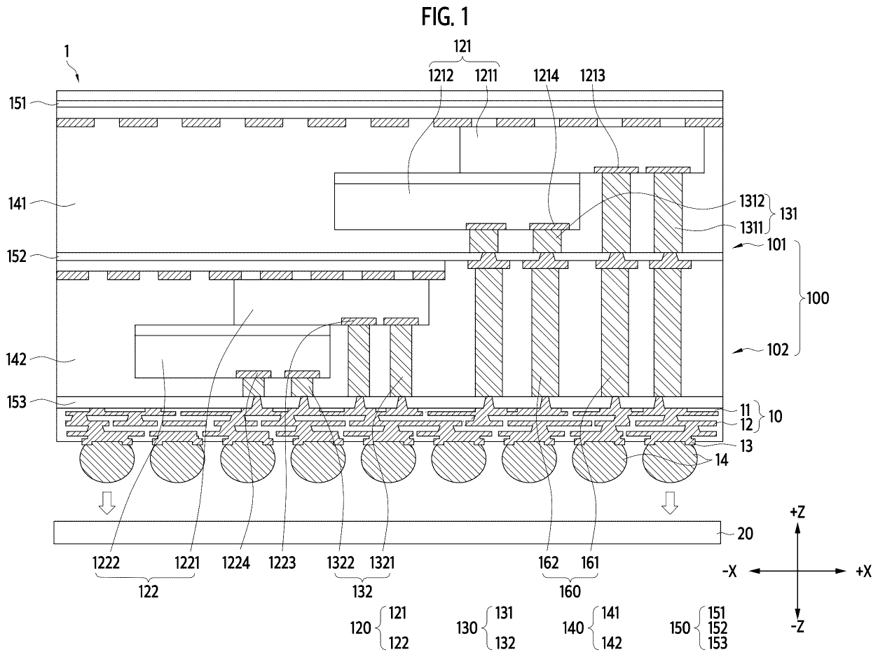

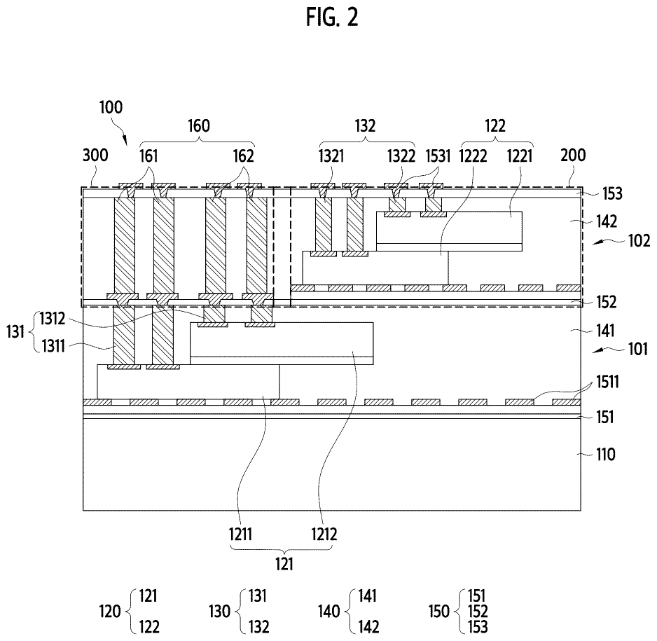

FIG. 1 is a diagram illustrating a semiconductor package 1 according to some example embodiments. FIG. 2 is a diagram illustrating the semiconductor package 1 according to some example embodiments. FIG. 2 is a diagram of an assembly 100 included in the semiconductor package 1 according to some example embodiments.

According to some example embodiments, the semiconductor package 1 may include a package substrate 10, a chip group 120, a wiring post 130, and a molding layer 140.

According to some example embodiments, the semiconductor package 1 may include a first structure 101 and a second structure 102. The first structure 101 and the second structure 102 may be stacked with each other. Each of the first structure 101 and the second structure 102 may be positioned over the package substrate 10. Here over means either being directly on or spaced apart from the substrate is a specified direction.

According to some example embodiments, the chip group 120 may include a first chip group 121 and a second chip group 122. The first chip group 121 may be a plurality of chips 1211, 1212 located within the first structure 101. The second chip group 122 may be a plurality of chips 1221, 1222 located within the second structure 102.

According to some example embodiments, the wiring post 130 may include a first wiring post 131 and a second wiring post 132. The first wiring post 131 may be a plurality of wiring posts 1311, 1312 located within the first structure 101. The second wiring post 132 may be a plurality of wiring posts 1321, 1322 located within the second structure 102.

According to some example embodiments, the molding layer 140 may include a first molding layer 141 and a second molding layer 142. The first molding layer 141 may be a molding layer located within the first structure 101. The second molding layer 142 may be a molding layer located within the second structure 102. The molding layer 140 may include an epoxy molding compound (EMC) material.

According to some example embodiments, the first structure 101 may include the first chip group 121, the first wiring post 131, and the first molding layer 141.

According to some example embodiments, the second structure 102 may include the second chip group 122, the second wiring post 132, and the second molding layer 142.

According to some example embodiments, the semiconductor package 1 may include a redistribution layer 150. The redistribution layer 150 may include a plurality of redistribution layers 151, 152, 153 spaced apart from each other. The redistribution layer 150 may include a first redistribution layer 151 electrically connected to the first chip group 121. The redistribution layer 150 may include a second redistribution layer 152 positioned between the first structure 101 and the second structure 102. The redistribution layer 150 may include a third redistribution layer 153 connected to the package substrate 10. Each of the first, second, and third redistribution layers 151, 152, 153 may be referred to as a “redistribution layer.”

According to some example embodiments, the package substrate 10 may be a wiring structure for a package. For example, the package substrate 10 may be a printed circuit board (PCB), a ceramic substrate, or an interposer. Alternatively, the package substrate 10 may also be a wiring structure for a wafer-level package (WLP) manufactured at a wafer level.

According to some example embodiments, the package substrate 10 may function as the redistribution layer. For example, the package substrate 10 may be a front redistribution layer (FRDL) of a fan-out package.

In some example embodiments, the package substrate 10 may be, but is not limited to, a glass substrate, a ceramic substrate, or a plastic substrate. For example, the package substrate 10 may include a resin impregnated with an inorganic filler together into a core material such as glass fiber (or glass cloth or glass fabric), for example, Prepreg, Ajinomoto Build-up Film (ABF), FR-4, or bismaleimide triazine (BT).

According to some example embodiments, the package substrate 10 may include a redistribution insulating layer 11 and a redistribution structure 12.

According to some example embodiments, when the package substrate 10 is the PCB, the redistribution insulating layer 11 may be composed of at least one material selected from phenolic resin, epoxy resin, and polyimide. The package substrate 10 may include at least one material selected from tetrafunctional epoxy, polyphenylene ether, epoxy/polyphenylene oxide, BT, thermount, cyanate ester, and liquid crystal polymer.

In some example embodiments, the redistribution insulating layer 11 may include a photoimageable dielectric. For example, the redistribution insulating layer 11 may include a photosensitive polymer. The photosensitive polymer may be formed of, for example, at least one of photosensitive polyimide, polybenzoxazole, phenolic polymer, and benzocyclobutene-based polymer. For another example, the redistribution insulating layer 11 may be formed of a silicon oxide layer, a silicon nitride layer, or a silicon oxynitride layer.

According to some example embodiments, the redistribution insulating layer 11 may include a plurality of insulating layers stacked. Each of the plurality of insulating layers may surround a wiring pattern and a wiring via of the redistribution structure 12 to be described below. The term “surrounding” or “covering” or “filling” as may be used herein may not require completely surrounding or covering or filling the described elements or layers, but may, for example, refer to partially surrounding or covering or filling the described elements or layers, for example, with voids, spaces, or other discontinuities throughout. The term “exposed,” may be used to describe relationships between elements and/or certain intermediate processes in fabricating a completed semiconductor device, but may not necessarily require exposure of the particular region, layer, structure or other element in the context of the completed device.

Although not illustrated, a surface of the redistribution insulating layer 11 may be covered by a solder resist. For example, a passivation layer may be formed on the surface of the redistribution insulating layer 11. The passivation layer formed on the surface of the redistribution insulating layer 11 may protect the redistribution structure 12 and other structures from external impacts or moisture. The passivation layer may include the solder resist. However, the present disclosure is not limited thereto.

According to some example embodiments, the redistribution structure 12 may be positioned within the redistribution insulating layer 11. The redistribution structure 12 may include wiring patterns and wiring vias connecting each wiring pattern. For example, the redistribution structure 12 may be a multilayer structure in which two or more wiring patterns or two or more wiring vias are stacked alternately. The wiring pattern may provide a horizontal connection between conductive components, and the wiring via may provide a vertical connection between conductive components. For example, the wiring pattern may extend in a second direction +X. The wiring via may connect wiring patterns spaced apart in a first direction +Z. In this case, the first direction +Z may refer to a direction perpendicular to a surface of the package substrate 10. The term “perpendicular” encompasses substantially perpendicular, and the term “parallel” encompasses substantially parallel.

In some example embodiments, the redistribution structure 12 may include a conductive material. For example, the redistribution structure 12 may include, but is not limited to, copper (Cu), aluminum (Al), silver (Ag), tin (Sn), gold (Au), nickel (Ni), lead (Pb), titanium (Ti), or an alloy thereof.

According to some example embodiments, an external connection terminal 14 may be formed on a lower portion of the package substrate. The external connection terminal 14 may be positioned on an external connection pad 13. The external connection terminal 14 may be in contact with the external connection pad 13. For example, the external connection terminal 14 may include a solder ball or a solder bump. For another example, the external connection terminal 14 may include a micro-bump. The external connection terminal 14 may be spherical or spheroidal but is not limited thereto. The number, gap, arrangement, form, and the like of the external connection terminal 14 are not limited to the drawings and may vary depending on designs. The external connection terminal 14 may include, for example, tin (Sn), indium (In), bismuth (Bi), antimony (Sb), copper (Cu), silver (Ag), zinc (Zn), lead (Pb), and a combination thereof but is not limited thereto.

According to some example embodiments, the external connection terminal 14 may electrically connect the redistribution structure 12 to an external device 20. Accordingly, the external connection terminal 14 may provide an electrical signal to the redistribution structure 12 or provide the external device 20 with an electrical signal provided from the redistribution structure 12.

For example, the external connection terminal 14 may provide an electrical signal for the chip group 120. The external connection terminal 14 may be provided with a signal input into the chip group 120. The external connection terminal 14 may be provided with a signal output from the chip 120.

According to some example embodiments, the first chip group 121 may be positioned over the package substrate 10 in the first direction +Z. The first chip group 121 may be positioned over the second chip group 122 in the first direction +Z. The first chip group 121 may be positioned to be spaced further apart from the package substrate 10 than the second chip group 122 in the first direction +Z. The first chip group 121 may be positioned within the first molding layer 141.

According to some example embodiments, the first chip group 121 may include at least one first chip 1211, 1212. For example, the first chip group 121 may include a plurality of first chips 1211, 1212. For example, the first chip group 121 may include a first-first chip 1211 and a first-second chip 1212. The first chips 1211, 1212 may be positioned over the package substrate 10 in the first direction +Z. FIGS. 1 and 2 illustrate that the first chip group 121 includes two first chips 1211, 1212, but example embodiments are not limited thereto. For example, the first chip group 121 may also include one first chip 1211 alone or may include three or more first chips.

For example, when the first chip group 121 includes the plurality of first chips 1211, 1212, the plurality of first chips 1211, 1212 may be positioned offset from each other in the second direction +X. Being positioned offset may represent being positioned to be staggered with a predetermined gap. For example, the plurality of first chips 1211, 1212 may not be positioned to completely overlap each other in the first direction +Z but may be positioned to be staggered in the second direction +X for some to overlap in the first direction +Z and for the others not to overlap in the first direction +Z. Sidewalls of the plurality of first chips 1211, 1212 may not be positioned on the same plane as each other but may be positioned to be spaced apart with a predetermined gap. As the plurality of first chips 1211, 1212 are positioned offset in the second direction +X, a first connection pad 1213 positioned in one chip 1211 of the plurality of first chips 1211, 1212 may not overlap with another first chip 1212 in the first direction +Z. Therefore, each of first connection pads 1213, 1214 may be connected to the first wiring post 131. Components or layers described with reference to “overlap” in a particular direction may be at least partially obstructed by one another when viewed along a line extending in the particular direction or in a plane perpendicular to the particular direction.

According to some example embodiments, the first chips 1211, 1212 may include the first connection pads 1213, 1214. The first-first chip 1211 may include a first-first connection pad 1213. The first-second chip 1212 may include a first-second connection pad 1214. The first connection pads 1213, 1214 may be positioned on one surface of the first chips 1211, 1212. In this case, one surface of the first chips 1211, 1212 may refer to a surface facing the package substrate 10 of each of the first chips 1211, 1212. The first connection pads 1213, 1214 may be exposed on one surface of the first chips 1211, 1212. The first connection pads 1213, 1214 may be in contact with the first wiring post 131. The first connection pads 1213, 1214 may be electrically connected to the first wiring post 131.

According to some example embodiments, the first wiring post 131 may extend between the first chips 1211, 1212 and the package substrate 10 in the first direction +Z. The first wiring post 131 may be positioned below the first chips 1211, 1212 in the first direction +Z. The first wiring post 131 may electrically connect the first chips 1211, 1212 to the package substrate 10. The first wiring post 131 may include a first-first wiring post 1311 connected to the first-first chip 1211 and a first-second wiring post 1312 connected to the first-second chip 1212.

According to some example embodiments, the first wiring posts 1311, 1312 may be connected to the first connection pads 1213, 1214. The first wiring posts 1311, 1312 may be positioned between the first connection pads 1213, 1214 and the second redistribution layer 152. The first wiring posts 1311, 1312 may electrically connect the first connection pads 1213, 1214 to the second redistribution layer 152.

According to some example embodiments, the first wiring post 131 may penetrate the first molding layer 141. The first wiring post 131 may be surrounded by the first molding layer 141. Specifically, a sidewall of the first wiring post 131 may be surrounded by the first molding layer 141.

According to some example embodiments, the first wiring post 131 may include a metal material such as titanium (Ti), copper (Cu), aluminum (Al), silver (Ag), tin (Sn), gold (Au), nickel (Ni), lead (Pb), or an alloy thereof. The first wiring post 131 may have a multilayer structure.

According to some example embodiments, the semiconductor package 1 may include an extension post 160. The extension post 160 may be located within the second structure 102. The extension post 160 may be surrounded by the second molding layer 142. The extension post 160 may extend between the second redistribution layer 152 and the third redistribution layer 153. The extension post 160 may connect the second redistribution layer 152 and the third redistribution layer 153.

According to some example embodiments, the extension post 160 may be electrically connected to the first wiring post 131. The extension post 160 may be positioned at a location corresponding to the first wiring post 131. For example, the first wiring post 131 may be positioned to overlap with the extension post 160 in the first direction +Z. The first wiring post 131 may be located in the first direction +Z with respect to the second redistribution layer 152, and the extension post 160 may be located in a third direction −Z opposite to the first direction +Z with respect to the second redistribution layer 152.

According to some example embodiments, the extension post 160 may include a first extension post 161 electrically connected to the first-first wiring post 1311 and a second extension post 162 electrically connected to the first-second wiring post 1312. The first-first wiring post 1311 may be located to overlap with the first extension post 161 in the first direction +Z. The first-second wiring post 1312 may be located to overlap with the second extension post 162 in the first direction +Z.

According to some example embodiments, the second chip group 122 may be positioned over the package substrate 10 in the first direction +Z. The second chip group 122 may be positioned below the first chip group 121 in the first direction +Z. The second chip group 122 may be positioned between the first chip group 121 and the package substrate 10. The second chip group 122 may be positioned more adjacent to (that is, closer to) the package substrate 10 than the first chip group 121. The second chip group 122 may be positioned within the second molding layer 142. The second chip group 122 may be surrounded by the second molding layer 142.

According to some example embodiments, the second chip group 122 may include at least one second chip 1221, 1222. For example, the second chip group 122 may include a plurality of second chips 1221, 1222. For example, the second chip group 122 may include a second-first chip 1221 and a second-second chip 1222. The second chips 1221, 1222 may be positioned over the package substrate 10 in the first direction +Z. FIGS. 1 and 2 illustrate that the second chip group 122 includes two second chips 1221, 1222, but example embodiments are not limited thereto. For example, the second chip group 122 may also include one second chip 1221 alone or may include three or more second chips.

For example, when the second chip group 122 includes the plurality of second chips 1221, 1222, the plurality of second chips 1221, 1222 may be positioned offset from each other in the second direction +X. For example, the plurality of second chips 1221, 1222 may not be positioned to completely overlap each other in the first direction +Z but may be positioned to be staggered in the second direction +X for some to overlap in the first direction +Z and for the others not to overlap in the first direction +Z. Sidewalls of the plurality of second chips 1221, 1222 may not be positioned on the same plane as each other but may be positioned to be spaced apart with a predetermined gap. As the plurality of second chips 1221, 1222 are positioned offset in the second direction +X, a second connection pad 1223 positioned in one 1221 of the plurality of second chips 1221, 1222 may not overlap with another second chip 1222 in the first direction +Z. Therefore, each of second connection pads 1223, 1224 may be connected to the second wiring post 132.

According to some example embodiments, the second chips 1221, 1222 may include the second connection pads 1223, 1224. The second-first chip 1221 may include a second-first connection pad 1223. The second-second chip 1222 may include a second-second connection pad 1224. The second connection pads 1223, 1224 may be positioned on one surface of the second chips 1221, 1222. In this case, one surface of the second chips 1221, 1222 may refer to a surface facing the package substrate 10 of each of the second chips 1221, 1222. The second connection pads 1223, 1224 may be exposed on one surface of the second chips 1221, 1222. The second connection pads 1223, 1224 may be in contact with the second wiring posts 1321, 1322. The second connection pads 1223, 1224 may be electrically connected to the second wiring posts 1321, 1322.

According to some example embodiments, the second wiring posts 1321, 1322 may extend between the second chips 1221, 1222 and the package substrate 10 in the first direction +Z. The second wiring posts 1321, 1322 may be positioned below the second chips 1221, 1222 in the first direction +Z. The second wiring posts 1321, 1322 may electrically connect the second chips 1221, 1222 to the package substrate 10. A second-first wiring post 1321 may electrically connect the second-first chip 1221 to the package substrate 10. A second-second wiring post 1322 may electrically connect the second-second chip 1222 to the package substrate 10. The second wiring posts 1321, 1322 may electrically connect the second chips 1221, 1222 to the package substrate 10 through the third redistribution layer 153.

According to some example embodiments, the second wiring posts 1321, 1322 may be connected to the second connection pads 1223, 1224. The second wiring posts 1321, 1322 may be positioned between the second connection pads 1223, 1224 and the package substrate 10. The second wiring posts 1321, 1322 may connect the second connection pads 1223, 1224 to the third redistribution layer 153. The third redistribution layer 153 may be electrically connected to the redistribution structure 12 of the package substrate 10. The second wiring posts 1321, 1322 may electrically connect the second connection pads 1223, 1224 to the package substrate 10 through the third redistribution layer 153. The third redistribution layer 153 may be referred to as a “substrate connection layer.”

According to some example embodiments, the second wiring post 132 may penetrate the second molding layer 142. The second wiring post 132 may be surrounded by the second molding layer 142. Specifically, a sidewall of the second wiring post 132 may be surrounded by the second molding layer 142.

According to some example embodiments, the second wiring post 132 may include a metal material such as titanium (Ti), copper (Cu), aluminum (Al), silver (Ag), tin (Sn), gold (Au), nickel (Ni), lead (Pb), or an alloy thereof. The second wiring post 132 may have a multilayer structure.

According to some example embodiments, each of the first chips 1211, 1212 and the second chips 1221, 1222 may include an integrated circuit (IC). The first chips 1211, 1212 and the second chips 1221, 1222 may have an active surface where the IC is formed and an inactive surface positioned opposite to the active surface. The active surface may be referred to as a front side surface, and the inactive surface may be referred to as a back side surface. For example, the front side surface may refer to a surface facing the package substrate 10. The inactive surface may refer to a surface positioned opposite to the front side surface.

According to some example embodiments, the first chips 1211, 1212 and the second chips 1221, 1222 may be a memory semiconductor chip. The memory semiconductor chip may be, for example, volatile memory such as dynamic random access memory (DRAM) or static random access memory (SRAM). Alternatively, the memory semiconductor chip may also be nonvolatile memory such as flash memory, phase-change random access memory (PRAM), magnetic random access memory (MRAM), ferroelectric random access memory (FeRAM), or resistive random access memory (RRAM). However, example embodiments are not limited thereto.

For example, at least some of the first chips 1211, 1212 and the second chips 1221, 1222 may be a logic semiconductor chip. The logic semiconductor chip may be, for example, an application processor (AP) such as a central processing unit (CPU), a graphic processing unit (GPU), a field-programmable gate array (FPGA), a digital signal processor, a cryptographic processor, a microprocessor, a microcontroller, and an application-specific IC (ASIC).

According to some example embodiments, the first molding layer 141 may be positioned over the second molding layer 142. The first molding layer 141 may be located farther from the package substrate 10 than the second molding layer 142.

According to some example embodiments, the first molding layer 141 may surround the first chip group 121. The first molding layer 141 may cover the first chip group 121. The first molding layer 141 may surround the first chips 1211, 1212 and the first wiring post 131.

According to some example embodiments, the second molding layer 142 may be positioned below the first molding layer 141. The second molding layer 142 may be positioned between the package substrate 10 and the first molding layer 141.

According to some example embodiments, the second molding layer 142 may surround the second chip group 122. The second molding layer 142 may surround the second chips 1221, 1222 and the second wiring post 132. The second molding layer 142 may surround the extension post 160.

According to some example embodiments, the second redistribution layer 152 may be positioned between the first molding layer 141 and the second molding layer 142. The second redistribution layer 152 may partition the first molding layer 141 from the second molding layer 142.

According to some example embodiments, the first molding layer 141 and the second molding layer 142 may include an insulating material. For example, the first molding layer 141 and the second molding layer 142 may include an insulating polymer material such as electromagnetic compatibility (EMC) materials. For another example, the first molding layer 141 and the second molding layer 142 may include a thermosetting resin such as an epoxy resin and a thermoplastic resin such as polyimide. The first molding layer 141 and the second molding layer 142 may include a filler. Each of the first molding layer 141 and the second molding layer 142 may include different filler contents.

According to some example embodiments, the semiconductor package 1 may include the redistribution layer 150. The redistribution layer 150 may include the first redistribution layer 151 connected to the first chip group 121. The first redistribution layer 151 may include a first redistribution pad 1511 connected to the first chip group 121. The first redistribution layer 151 may form an upper surface of the package substrate 1 after the assembly 100 is stacked on the package substrate 10. The first redistribution layer 151 may be referred to as an “upper redistribution layer.”

According to some example embodiments, the semiconductor package 1 may include the redistribution layer 150. The redistribution layer 150 may include the second redistribution layer 152 positioned between the first molding layer 141 and the second molding layer 142. The second redistribution layer 152 may be positioned between the first structure 101 and the second structure 102. The second redistribution layer 152 may be electrically connected to each of the first chip group 121 and the second chip group 122. The second redistribution layer 152 may be spaced apart from the package substrate 10 after the assembly 100 is stacked on the package substrate 10. The second redistribution layer 152 may be referred to as a “middle redistribution layer.”

According to some example embodiments, the semiconductor package 1 may include the redistribution layer 150. The redistribution layer 150 may include the third redistribution layer 153 connected to the second chip group 122. The third redistribution layer 153 may include a third redistribution pad 1531 connected to the second chip group 122. The third redistribution layer 153 may connect the second chip group 122 to the package substrate 10. The third redistribution layer 153 may be coupled to the package substrate 10. The third redistribution pad 1531 may be electrically connected to the redistribution structure 12 of the package substrate 10. The third redistribution layer 153 may be a lower surface of the assembly 100 coupled to the package substrate 10. The third redistribution layer 153 may be referred to as a “lower redistribution layer.” The third redistribution layer 153 may be referred to as the “substrate connection layer.”

Referring to FIGS. 1 and 2, the semiconductor package 1 may include the assembly 100. The assembly 100 may include the chip group 120, the wiring post 130, the molding layer 140, and the redistribution layer 150. As illustrated in FIG. 2, the assembly 100 may be manufactured on a carrier substrate 110. The assembly 100 manufactured on the carrier substrate 110, after the carrier substrate 110 is removed, may be turned over so that the lower redistribution layer 153 faces the package substrate 10 and stacked on the package substrate 10, as illustrated in FIG. 1. For example, FIG. 1 may be a diagram of the second structure 102 and the first structure 101 stacked in sequence in the first direction +Z based on the package substrate 10, and FIG. 2 may be a diagram of the first structure 101 and the second structure 102 stacked in sequence in the third direction −Z opposite to the first direction +Z based on the carrier substrate 110.

Referring to FIG. 2, the assembly 100 may include a block (for example, a block 200). The assembly 100 may be a structure in which a plurality of blocks (for example, blocks 101, 200, 300) are positioned and coupled.

According to some example embodiments, the first structure 101 may be one of the plurality of blocks (for example, the blocks 101, 200, 300). When the first structure 101 is one of the plurality of blocks, the first structure 101 may be referred to as a “first block.”

According to some example embodiments, the assembly 100 may include the block 200. The block 200 may include the second chip group 122, the second wiring post 132, and a portion of the second molding layer 142. The block 200 may be stacked with the second redistribution layer 152. The block 200 may be a “second block 200” stacked with the first block (for example, the first structure 101).

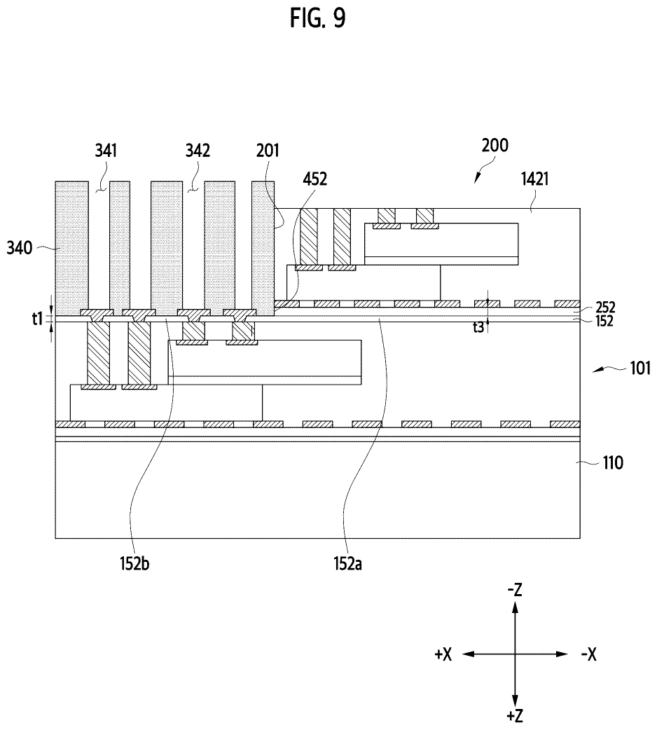

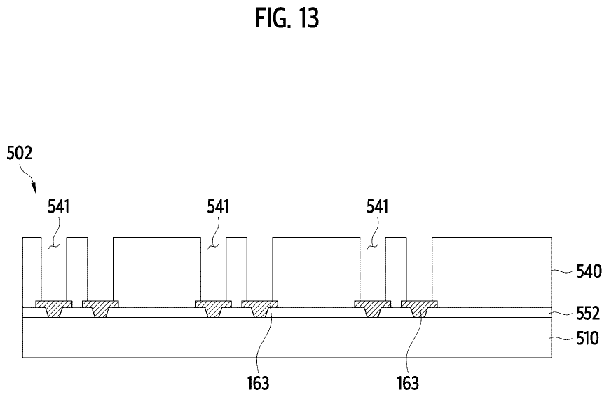

According to some example embodiments, the assembly 100 may include a post block 300. The post block 300 may include the extension post 160 and a portion of the second molding layer 142. The post block 300 may be stacked with the second redistribution layer 152. As illustrated in FIGS. 9 to 12, the post block 300, in a state where the block 200 is positioned above the first structure 101, may be manufactured by forming the extension post 160 and a portion 1422 of the second molding layer 142 at one side of the block 200. As illustrated in FIGS. 13 to 19, a post block 500 according to an example embodiment of the present disclosure may be positioned independently at one side of the block 200 after manufacturing the extension post 160, a portion of the second molding layer 142, and a post block wiring layer 552 in a form of the post block 500.

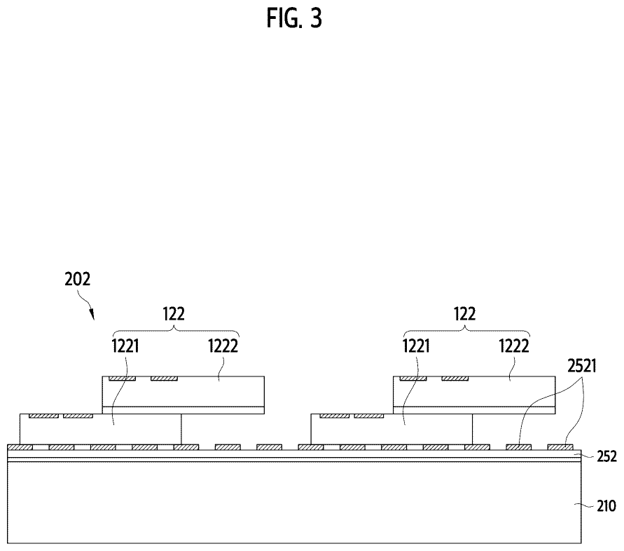

FIGS. 3 to 12 are diagrams illustrating a method of manufacturing the assembly 100 according to an example embodiment of the present disclosure. FIGS. 3 to 7 are diagrams illustrating a method 202, 203, 204, 205, 206 of manufacturing the block 200 according to an example embodiment of the present disclosure.

Referring to FIG. 3, the method of manufacturing the assembly 100 may include operation 202 of positioning a plurality of chip groups 122 to be spaced apart from each other. The plurality of chip groups 122 may include a plurality of second chip groups 122. Each of the plurality of chip groups 122 may include the second-first chip 1221 and the second-second chip 1222. The plurality of chip groups 122 may be positioned over a base substrate 210. A block wiring layer 252 may be positioned above the base substrate 210. The block wiring layer 252 may include a block wiring pad 2521. The plurality of chip groups 122 may be positioned to be spaced apart from each other on the block wiring layer 252. The plurality of chip groups 122 may be electrically connected to the block wiring pad 2521. The second-first chip 1221 and the second-second chip 1222 may be stacked in sequence on the block wiring layer 252.

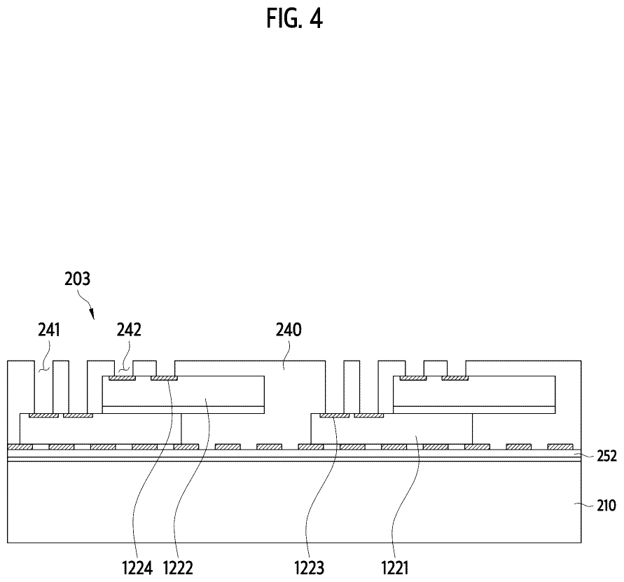

Referring to FIG. 4, the method of manufacturing the assembly 100 may include operation 203 of positioning a mask layer 240 to surround the plurality of chip groups 122. The mask layer 240 may be positioned to surround the second-first chip 1221 and the second-second chip 1222. The mask layer 240 may be positioned on the block wiring layer 252. The mask layer 240 may include a material (for example, a photosensitive material) modified by light. The mask layer 240 may include a photosensitive layer. The mask layer 240 may include a plurality of opening parts 241, 242. The plurality of opening parts 241, 242 may be formed at locations corresponding to the second connection pads 1223, 1224. The second connection pads 1223, 1224 may be exposed to the outside of the mask layer 240 through the plurality of opening parts 241, 242. The plurality of opening parts 241, 242 may include a first opening part 241 formed at a location corresponding to the second-first connection pad 1223 and a second opening part 242 formed at a location corresponding to the second-second connection pad 1224.

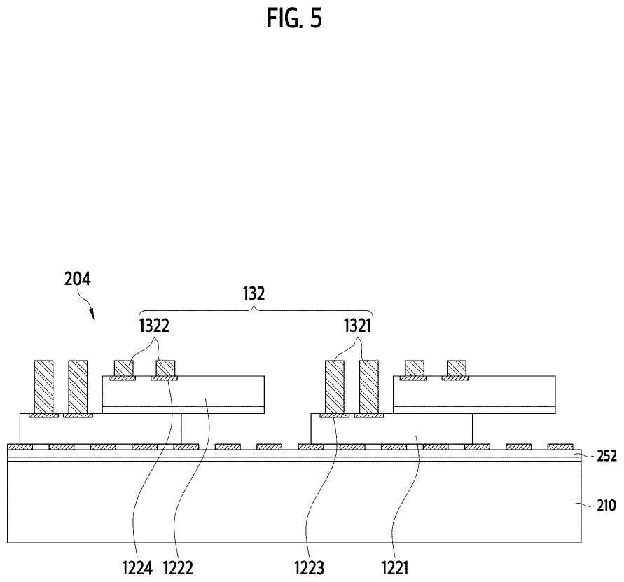

Referring to FIG. 5, the method of manufacturing the assembly 100 may include operation 204 of forming the second wiring post 132. The second wiring post 132 may include a metal material (for example, copper (Cu)) inserted into a plurality of opening parts (for example, the plurality of opening parts 241, 242 of FIG. 4). The second wiring post 132 may be formed by a predetermined forming manner (for example, electroplating or electroless plating). The second wiring post 132 may be formed at locations corresponding to the second connection pads 1223, 1224. The second wiring post 132 may extend from the second connection pads 1223, 1224. The second wiring post 132 may include the second-first wiring post 1321 connected to the second-first connection pad 1223 and the second-second wiring post 1322 connected to the second-second connection pad 1224.

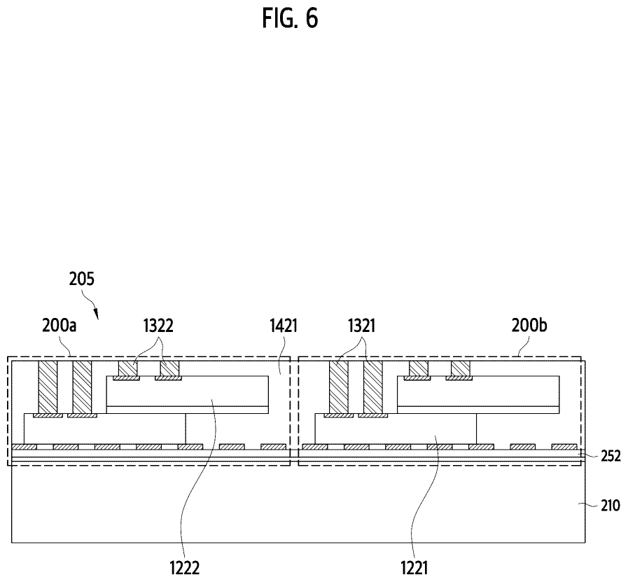

Referring to FIG. 6, the method of manufacturing the assembly 100 may include operation 205 of forming a first molding portion 1421. The first molding portion 1421 described with reference to FIG. 6 may be a portion of the second molding layer 142 described with reference to FIGS. 1 and 2. The first molding portion 1421 may include an EMC material. The first molding portion 1421 may be positioned to surround the second-first chip 1221 and the second-second chip 1222. The first molding portion 1421 may be positioned to surround the second-first wiring post 1321 and the second-second wiring post 1322. The first molding portion 1421 may be positioned on the block wiring layer 252.

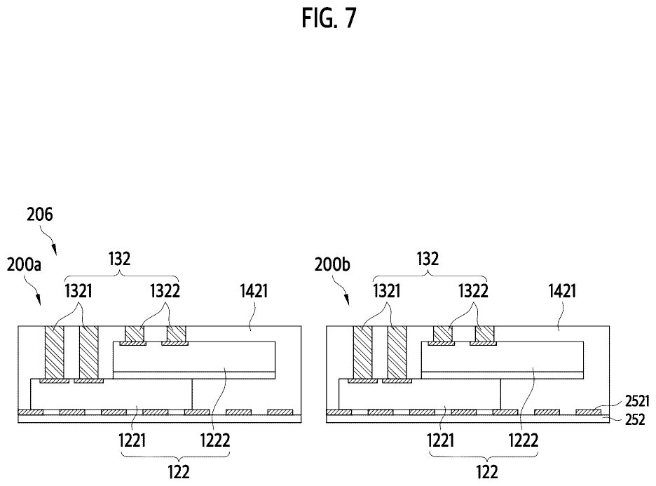

Referring to FIG. 7, the method of manufacturing the assembly 100 may include operation 206 of cutting a plurality of blocks 200a, 200b. Each of the plurality of blocks 200a, 200b described with reference to FIG. 7 may be the block 200 described with reference to FIGS. 1 and 2. For example, one of the plurality of blocks 200a, 200b may be the block 200 of the assembly 100 and be positioned within a second structure (for example, the second structure 102 of FIG. 2). Each of the plurality of blocks 200a, 200b may be a portion cut from the structure illustrated in FIG. 6. Each of the plurality of blocks 200a, 200b may include the second chip group 122, the second wiring post 132, the first molding portion 1421, and the block wiring layer 252 including the block wiring pad 2521.

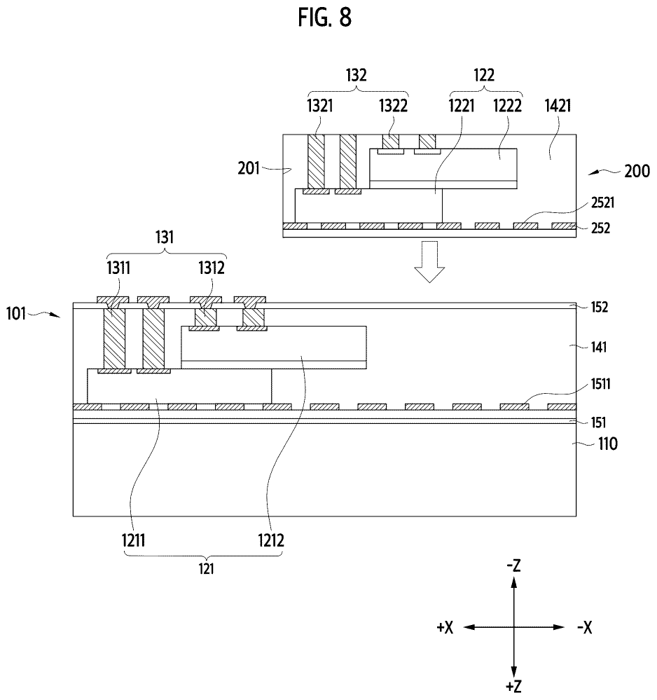

Referring to FIG. 8, the method of manufacturing the assembly 100 may include an operation of positioning the block 200 over the first structure 101. The block 200 may be stacked on the second redistribution layer 152. The block wiring layer 252 may be attached to the second redistribution layer 152. The block 200 may be stacked on the second redistribution layer 152 so that at least a portion of the second chip group 122 is located offset from the first chip group 121 in the first direction +Z. The block 200 may be stacked on the second redistribution layer 152 so that the second wiring post 132 is located offset from the first wiring post 131 in the first direction +Z. The first molding portion 1421 may be spaced apart from the first molding layer 141 with the second redistribution layer 152 in between. The block wiring layer 252 may be located between the first molding portion 1421 and the first molding layer 141.

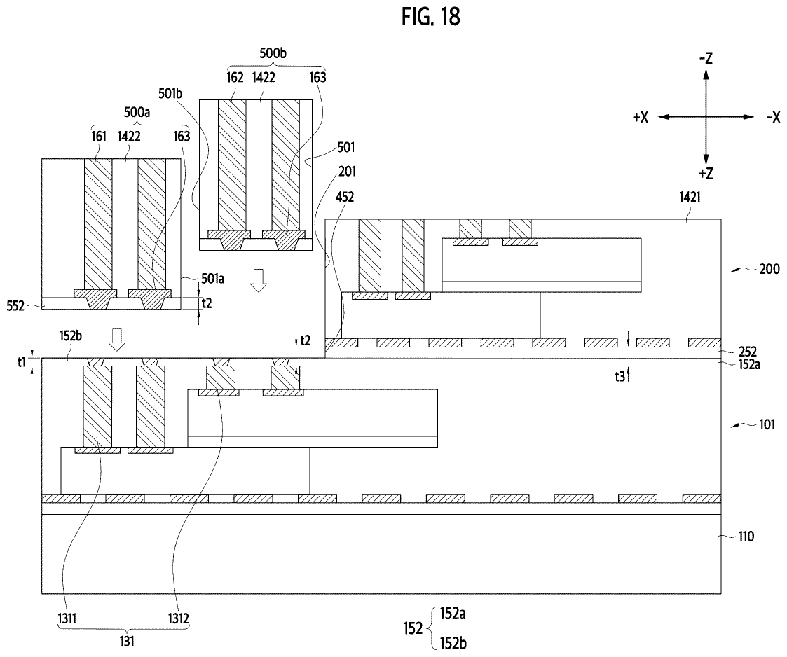

Referring to FIG. 9, the block 200 may be stacked on the second redistribution layer 152. The block wiring layer 252 may be attached to the second redistribution layer 152. The second redistribution layer 152 may include a first wiring portion 152a to which the block wiring layer 252 is attached and a second wiring portion 152b to which the block wiring layer 252 is not attached. The first wiring portion 152a may overlap with the block wiring layer 252 in the first direction +Z. The second wiring portion 152b may be located offset from the block wiring layer 252 in the first direction +Z, and hence, the second wiring portion 152b is dislocated from the block wiring layer 252. The second redistribution layer 152 may have a first thickness t1. The block wiring layer 252 may have a second thickness t3. An area corresponding to the block 200 in the first direction +Z of the assembly 100 may have a wiring layer thickness (e.g. wiring layer thickness t3 of FIG. 18) equal to a sum of the thicknesses of the second redistribution layer 152 and the block wiring layer 252. Another area located offset from the block 200 in the first direction +Z of the assembly 100 may have a wiring layer thickness equal to the first thickness t1 of the second redistribution layer 152. The assembly 100 may include a step portion 452. The step portion 452 may be formed in an area where an edge of the block wiring layer 252 is located. The step portion 452 may overlap with a block surface 201 in the first direction +Z.

Referring to FIG. 9, the method of manufacturing the assembly 100 may include an operation of positioning a masking body 340 at a lateral side of the block 200. The masking body 340 may include a material (for example, a photosensitive material) modified by light. The masking body 340 may include a photosensitive layer. The masking body 340 may be positioned at a lateral side of the first molding portion 1421. The masking body 340 may include a plurality of holes 341, 342. A portion of the second redistribution layer 152 may be exposed to the outside of the masking body 340 through the plurality of holes 341, 342.

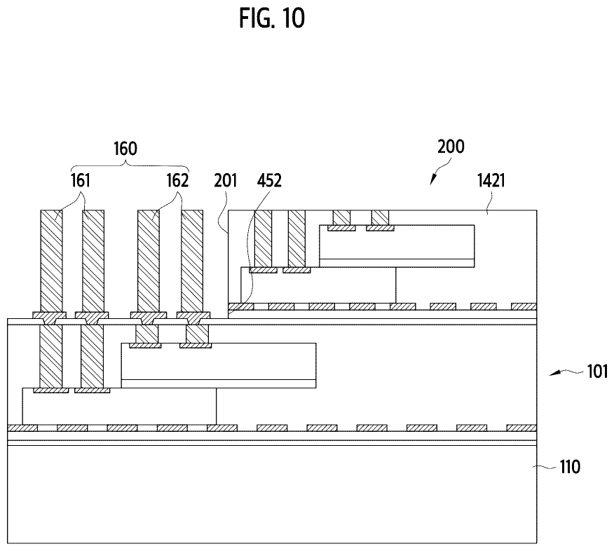

Referring to FIG. 10, the method of manufacturing the assembly 100 may include an operation of forming the extension post 160. The extension post 160 may include a metal material (for example, copper (Cu)) inserted into a plurality of holes (for example, the plurality of holes 341, 342 of FIG. 9). For example, the first extension post 161 may be formed by plating with the metal material within a first hole 341, and the second extension post 162 may be formed by plating with the metal material within a second hole 342. The extension post 160 may extend from the second redistribution layer 152. The block surface 201 of the block 200 may be spaced apart from one side of the extension post 160. The step portion 452 may be spaced apart from one side of the extension post 160.

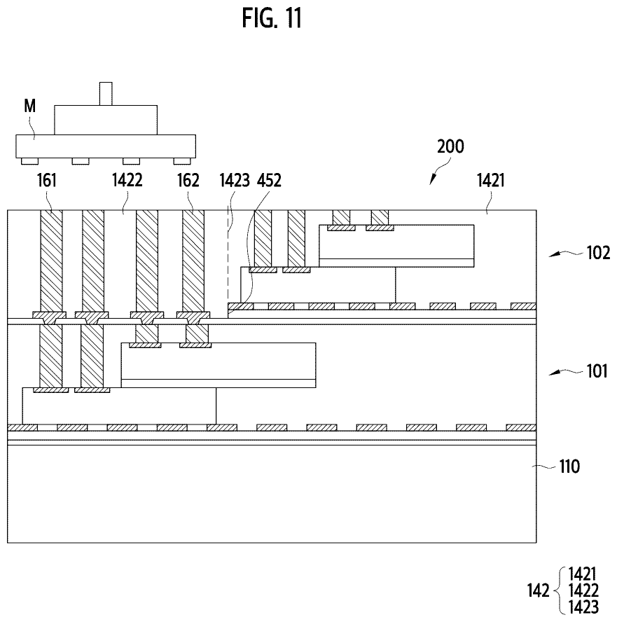

Referring to FIG. 11, the method of manufacturing the assembly 100 may include an operation of forming a second molding portion 1422. The second molding portion 1422 may be a portion of the second molding layer 142 described with reference to FIGS. 1 and 2. The second molding portion 1422 may be a remaining portion excluding the first molding portion 1421 from the second molding layer 142. The second molding portion 1422 may include an identical material (for example, the EMC material) to the first molding portion 1421. The second molding portion 1422 may be positioned to surround the extension posts 161, 162. The second molding portion 1422 may be in contact with the first molding portion 1421 of the block 200. The second molding portion 1422 may be in contact with the block surface 201 of the block 200 to form a boundary portion 1423. The boundary portion 1423 may be a boundary surface on which the first molding portion 1421 and the second molding portion 1422 are in contact. The second molding portion 1422 may be in contact with the step portion 452.

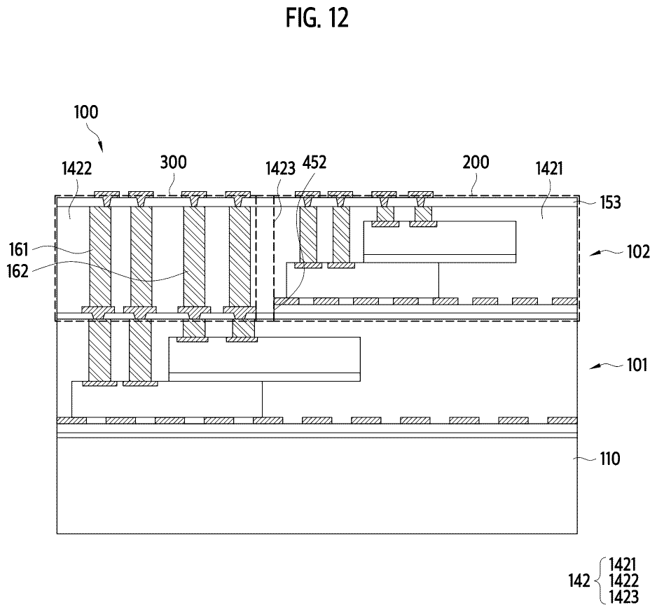

Referring to FIGS. 11 and 12, the second structure 102 may include the post block 300. The post block 300 may include the extension posts 161, 162 and the second molding portion 1422 surrounding the extension posts 161, 162. The post block 300 may be positioned at one side of the block 200 by the method described with reference to FIGS. 8 to 11. The post block 300 may be in contact with the block surface 201 of the block 200 and may be in contact with the block surface 201 to form the boundary portion 1423.

Referring to FIG. 12, the method of manufacturing the assembly 100 may include an operation of positioning the third redistribution layer 153. After the second molding portion 1422 is formed, as illustrated in FIG. 11, a surface of the second molding portion 1422 may form the same plane as a surface of the first molding portion 1421 by a machining tool M. The third redistribution layer 153 may be stacked on the first and second molding portions 1421, 1422.

Referring to FIG. 12, the second molding layer 142 may include the first molding portion 1421, the second molding portion 1422, and the boundary portion 1423. Each of the first molding portion 1421, the second molding portion 1422, and the boundary portion 1423 may be a portion of the second molding layer 142. The first molding portion 1421 may be a portion of the second molding layer 142 manufactured in a state included in the block 200 by the method described with reference to FIGS. 3 to 7. The second molding portion 1422 may be a remaining portion of the second molding layer 142 manufactured in a state included in the post block 300 by the method described with reference to FIGS. 8 to 11. The boundary portion 1423 may be a boundary surface on which the first molding portion 1421 and the second molding portion 1422 are in contact. The second structure 102 may include the second molding layer 142 including the first molding portion 1421, the second molding portion 1422, and the boundary portion 1423.

Referring to FIG. 12, the boundary portion 1423 may be formed as a block surface (for example, the block surface 201 of FIG. 10) of the block 200 is formed first, and then, the second molding portion 1422 of the post block 300 is formed. For example, since the second molding portion 1422 of the post block 300 is solidified after the first molding portion 1421 of the block 200 is solidified, the boundary portion 1423 may be formed due to different time points of each of the molding portions 1421, 1422 being solidified. A degree of hardness of the boundary portion 1423 may be different from a degree of hardness of the first molding portion 1421. The degree of hardness of the boundary portion 1423 may be different from a degree of hardness of the second molding portion 1422. The roughness of the boundary portion 1423 may be different from the roughness of the first molding portion 1421. The roughness of the boundary portion 1423 may be different from the roughness of the second molding portion 1422.

Referring to FIGS. 1 and 12, the assembly 100 manufactured by the method described with reference to FIGS. 3 to 12 may be stacked with the package substrate 10. The assembly 100 may be stacked on the package substrate 10 after the carrier substrate 110 is removed. The carrier substrate 110 may be a wafer or a panel provided to manufacture the assembly 100. The assembly 100 may be positioned for the third redistribution layer 153 to face the package substrate 10 and may be stacked on the package substrate 10. The third redistribution layer 153 may be attached to the package substrate 10.

FIGS. 13 to 19 are diagrams illustrating a method of manufacturing the assembly 100 according to an example embodiment of the present disclosure. FIGS. 13 to 16 are diagrams illustrating a method 502, 503, 504, 505 of manufacturing the post block 500 according to an example embodiment of the present disclosure.

Referring to FIG. 13, the method of manufacturing the assembly 100 may include operation 502 of positioning a masking body 540 above a base substrate 510. The masking body 540 may include a material (for example, a photosensitive material) modified by light. The masking body 540 may include a photosensitive layer. The post block wiring layer 552 may be positioned on the base substrate 510. An extension post pad 163 may be positioned on the post block wiring layer 552. A plurality of extension post pads 163 may be positioned to be spaced apart from each other along a surface of the post block wiring layer 552. The masking body 540 may include a plurality of holes 541. Each of the plurality of holes 541 may correspond to each of the plurality of extension post pads 163. The plurality of extension post pads 163 may be exposed to the outside of the masking body 540 through the plurality of holes 541.

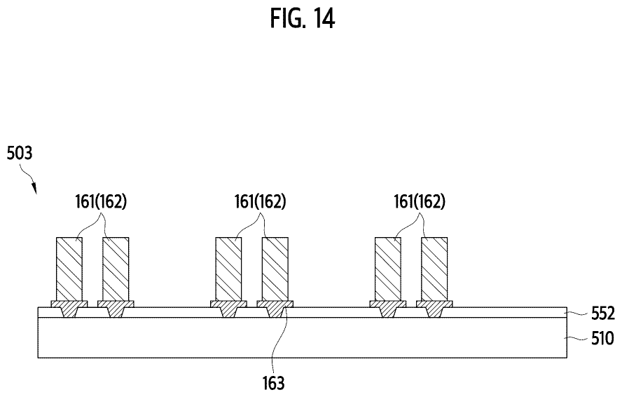

Referring to FIG. 14, the method of manufacturing the assembly 100 may include operation 503 of forming the extension posts 161, 162. The extension posts 161, 162 may include a metal material (for example, copper (Cu)) inserted into a plurality of holes (for example, the plurality of holes 541 of FIG. 13). The extension posts 161, 162 may be connected to the extension post pad 163. The extension posts 161, 162 may extend from the extension post pad 163 in a direction away from the post block wiring layer 552.

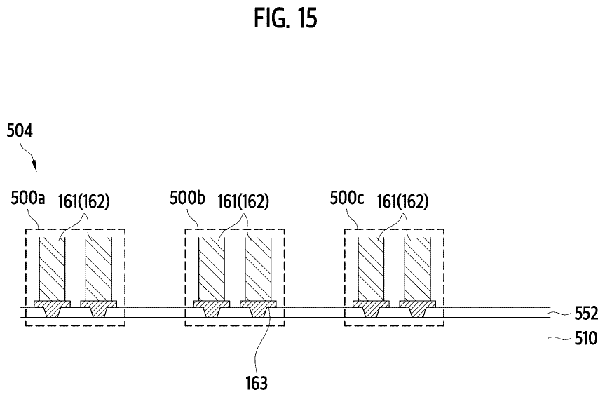

Referring to FIG. 15, the method of manufacturing the assembly 100 may include operation 504 of forming the second molding portion 1422. The second molding portion 1422 may be a portion of the second molding layer 142 described with reference to FIGS. 1 and 2. The second molding portion 1422 may be a remaining portion of the second molding layer 142 excluding the first molding portion 1421 included in the block 200 described with reference to FIGS. 1 to 12. The second molding portion 1422 may be positioned to surround the extension posts 161, 162. The second molding portion 1422 may be positioned to surround the extension post pad 163. The second molding portion 1422 may be positioned on the post block wiring layer 552. The second molding portion 1422 may include an EMC material.

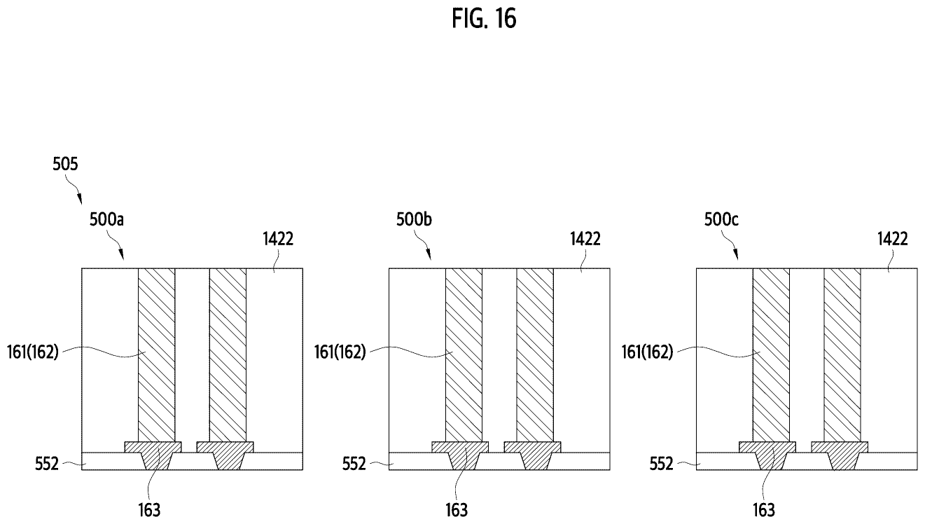

Referring to FIG. 16, the method of manufacturing the assembly 100 may include operation 505 of forming a plurality of post blocks 500a, 500b, 500c. As illustrated in FIG. 15, each of the plurality of extension posts 161, 162 surrounded by the second molding portion 1422 may be cut as the plurality of post blocks 500a, 500b, 500c. Each of the plurality of post blocks 500a, 500b, 500c may include the extension posts 161, 162, the extension post pad 163, the post block wiring layer 552, and the second molding portion 1422.

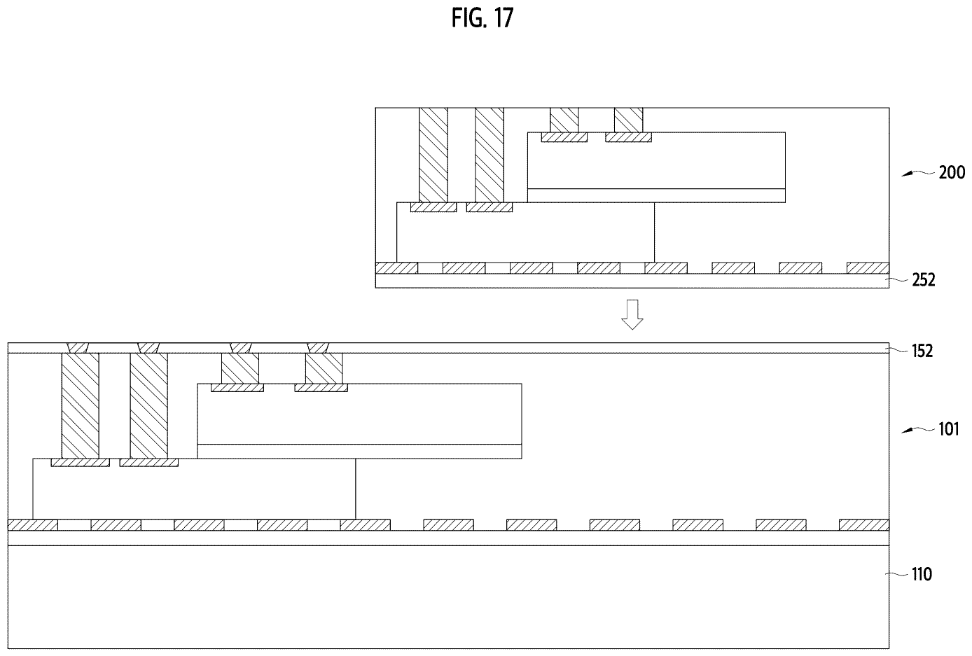

Referring to FIG. 17, the method of manufacturing the assembly 100 may include an operation of positioning the block 200 over the first structure 101. The description of the first structure 101 described with reference to FIGS. 1 to 12 may be applied identically to a description of the first structure 101. The description of the block 200 described with reference to FIGS. 1 to 12 may be applied identically to a description of the block 200. The block 200 may be manufactured by the method described with reference to FIGS. 3 to 12. The block wiring layer 252 of the block 200 may be attached to the second redistribution layer 152.

Referring to FIG. 18, the method of manufacturing the assembly 100 may include an operation of positioning post blocks 500a, 500b over the first structure 101. The post blocks 500a, 500b may be positioned at a lateral side of the block 200. Post block surfaces 501 of the post blocks 500a, 500b may face the block surface 201 of the block 200 in a lateral direction. The post blocks 500a, 500b may include a plurality of post blocks 500a, 500b arranged in a lateral direction (for example, the second direction +X) of the block 200. For example, the post blocks 500a, 500b may include a first post block 500a and a second post block 500b having post block surfaces 501a, 501b, respectively, which face each other. Each of the first and second post blocks 500a, 500b may include the extension post pad 163, the post block wiring layer 552, and the second molding portion 1422. The first post block 500a and the second post block 500b may be spaced apart from each other in the lateral direction. A first boundary surface 501a of the first post block 500a and a second boundary surface 501b of the second post block 500b may be spaced apart from each other. The first boundary surface 501a and the second boundary surface 501b may face each other when the first post block 500a and the second post block 500b are stacked on the second redistribution layer 152. In another embodiment, a first boundary surface 501a of the first post block 500a may contact the second boundary surface 501b of the second post block 500b. The post block 500 includes a plurality of post blocks 500a, 500b arranged in a direction substantially parallel to a face of the package substrate 10.

Referring to FIG. 18, the first post block 500a may include the first extension post 161 electrically connected to the first-first wiring post 1311. The first extension post 161 may be located to overlap with the first-first wiring post 1311 in the first direction +Z. The second post block 500b may include the second extension post 162 electrically connected to the first-second wiring post 1312. The second extension post 162 may be located to overlap with the first-second wiring post 1312 in the first direction +Z.

Referring to FIG. 18, the post block surfaces 501a, 501b of each of the plurality of post blocks 500a, 500b may face each other. As the post block surfaces 501a, 501b of each of the plurality of post blocks 500a, 500b are spaced apart from each other, a space may be formed between the first boundary surface 501a of the first post block 500a and the second boundary surface 501b of the second post block 500b.

Referring to FIG. 18, the post blocks 500a, 500b may be stacked on the second redistribution layer 152. The post block wiring layer 552 may be attached to the second redistribution layer 152. The second redistribution layer 152 may include the first wiring portion 152a and the second wiring portion 152b. The description of the first and second wiring portions 152a, 152b described with reference to FIGS. 1 to 12 may be applied identically to a description of the first and second wiring portions 152a, 152b. The block wiring layer 252 may be stacked on the first wiring portion 152a to form the step portion 452. The description of the step portion 452 described with reference to FIGS. 1 to 12 may be applied identically to a description of the step portion 452. A thickness t2 of the post block wiring layer 552 may be substantially identical to the thickness t2 of the block wiring layer 252. The post block wiring layer 552 of the post blocks 500a, 500b may be positioned in a lateral direction (for example, the second direction +X) from the step portion 452 and aligned with the block wiring layer 252 of the block 200 in the lateral direction +X. One surface of the post block wiring layer 552 may be in contact with the step portion 452. Accordingly, as the post block wiring layer 552 compensates for a thickness difference formed in the vicinity of the step portion 452, the thickness of a wiring layer between the first structure 101 and the second structure 102 may be formed to be uniform in a lateral direction (for example, the second direction +X).

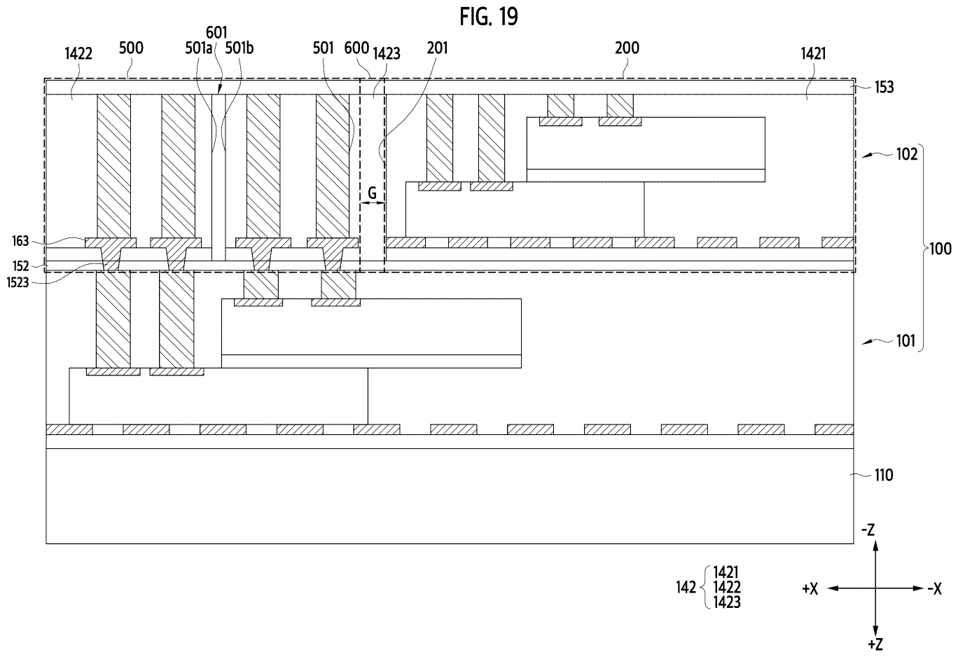

Referring to FIG. 19, the method of manufacturing the assembly 100 may include an operation of forming the boundary portion 1423 between the block 200 and the post block 500. The block 200 and the post block 500 may be spaced apart from each other in a lateral direction (for example, the second direction +X). A gap G may be formed between the block surface 201 and the post block surface 501. The boundary portion 1423 may be positioned between the block 200 and the post block 500. The boundary portion 1423 may be positioned between the block surface 201 and the post block surface 501 and may be in contact with each of the block surface 201 and the post block surface 501. The boundary portion 1423 may be a portion of the second molding layer 142. For example, the boundary portion 1423 may be a remaining portion of the second molding layer 142 excluding the first molding portion 1421 included in the block 200 and the second molding portion 1422 included in the post block 500. The boundary portion 1423 may be a boundary wall positioned between the block 200 and the post block 500. For example, the boundary portion 1423 may refer to the boundary wall having a width of the gap G and partitioning the block 200 from the post block 500. The boundary portion 1423 may be formed as a material of a filler 600 injected between the block 200 and the post block 500 is solidified. The filler 600 between the block 200 and the post block 500 may form the boundary portion 1423 that is a portion of the second molding layer 142. The third redistribution layer 153 may be stacked on the first molding portion 1421, the second molding portion 1422, and the boundary portion 1423.

Referring to FIG. 19, a first degree of hardness of the first molding portion 1421 may be different from a second degree of hardness of the second molding portion 1422. A third degree of hardness of the boundary portion 1423 may be a value between the first degree of hardness and the second degree of hardness. The semiconductor package according to example embodiments of the present disclosure may prevent warpage in the semiconductor package by forming the degrees of hardness of the second molding layer 142 constituting the second structure 102 to be different along the second direction +X. For example, the semiconductor package according to example embodiments of the present disclosure may increase the flatness of the second molding layer 142 formed along the second direction +X by forming the degrees of hardness of the first molding portion 1421 and the second molding portion 1422 to be different from each other and forming the third degree of hardness of the boundary portion 1423 as the value between the first degree of hardness of the first molding portion 1421 and the second degree of hardness of the second molding portion 1422.

Referring to FIG. 19, the first boundary surface 501a and the second boundary surface 501b may be spaced apart from each other. The assembly 100 may include a second filler 601 positioned between the first boundary surface 501a and the second boundary surface 501b. The second filler 601 may be in contact with each of the first boundary surface 501a and the second boundary surface 501b. A degree of hardness of the second filler 601 may be different from a degree of hardness of a post block (for example, the post blocks 500a, 500b of FIG. 18).

Referring to FIGS. 18 and 19, the block 200 and the post blocks 500a, 500b may be stacked above the first structure 101. A stacking process of the block 200 and the post blocks 500a, 500b may be performed at a wafer level. As stacking the block 200 and the post blocks 500a, 500b is performed at a wafer level, the semiconductor package 1 according to example embodiments of the present disclosure may form the second structure 102 by positioning the second post block 500b between the block 200 and the first post block 500a and positioning the fillers 600, 601 between each block (for example, the block 200, the first post block 500a, and the second post block 500b).

Referring to FIG. 19, the extension post pad 163 may be electrically connected to the second redistribution layer 152. The second redistribution layer 152 may include a pad connector 1523 connected to the extension post pad 163. The pad connector 1523 may be a conductive structure formed in the second redistribution layer 152. The extension post pad 163 may be exposed to the outside of a post block wiring layer (for example, the post block wiring layer 552 of FIG. 18) and may be connected to the pad connector 1523 of the second redistribution layer 152.

Referring to FIGS. 1 and 19, the assembly 100 manufactured by the method described with reference to FIGS. 13 to 19 may be stacked with the package substrate 10. The assembly 100 may be stacked on the package substrate 10 after the carrier substrate 110 is removed. The carrier substrate 110 may be a wafer or a panel provided to manufacture the assembly 100. The assembly 100 may be positioned for the third redistribution layer 153 to face the package substrate 10 and may be stacked on the package substrate 10. The third redistribution layer 153 may be attached to the package substrate 10.

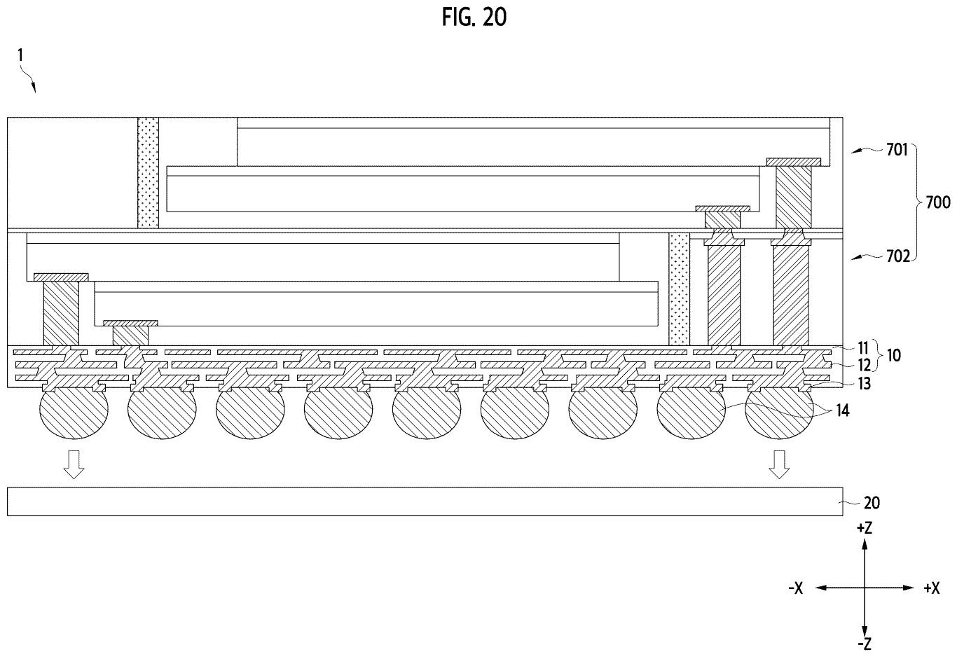

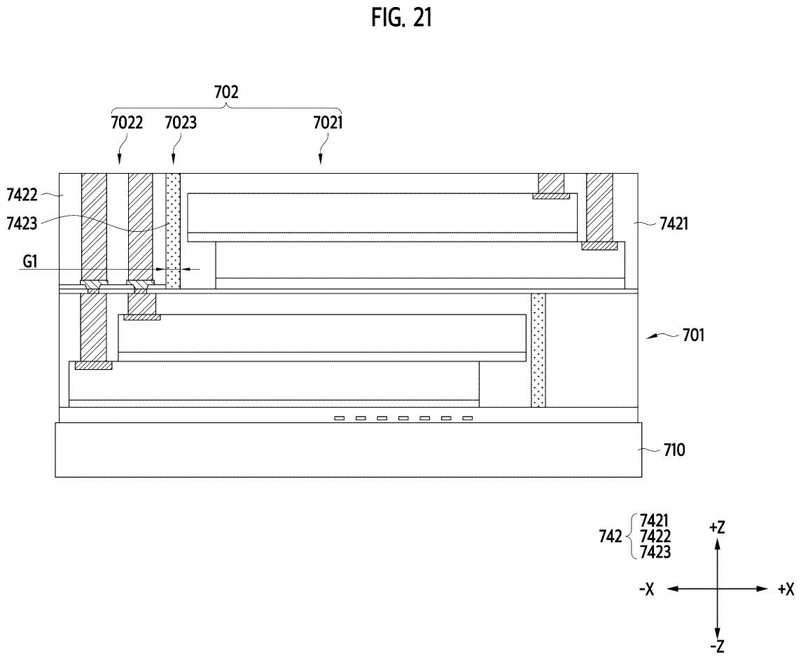

FIG. 20 is a diagram of the semiconductor package 1 according to another example embodiment of the present disclosure. FIG. 21 is a diagram of an assembly 700 included in the semiconductor package 1 according to another example embodiment and a carrier substrate 710 for manufacturing the assembly 700.

According to another example embodiment, the semiconductor package 1 may include the package substrate 10. The description of the package substrate 10 described with reference to FIGS. 1 to 19 may be applied identically to a description of the package substrate 10. For example, the package substrate 10 may include the redistribution insulating layer 11, the redistribution structure 12, the external connection pad 13, and the external connection terminal 14.

According to another example embodiment, the semiconductor package 1 may include the assembly 700. The assembly 700 may include a first structure 701 and a second structure 702. The description of the first structure 101 and the second structure 102 described with reference to FIGS. 1 to 19 may be applied identically to a description of the first structure 701 and the second structure 702.

According to another example embodiment, the second structure 702 may include a block 7021. The description of the block 200 described with reference to FIGS. 1 to 19 may be applied identically to a description of the block 7021. The block 7021 may be stacked with the first structure 701. The block 7021 may include a first molding portion 7421. The description of the first molding portion 1421 described with reference to FIGS. 1 to 19 may be applied identically to a description of the first molding portion 7421.

According to another example embodiment, the second structure 702 may include a post block 7022. The description of the post blocks 300, 500 described with reference to FIGS. 1 to 19 may be applied identically to a description of the post block 7022. The post block 7022 may be stacked with the first structure 701. The post block 7022 may be spaced apart from the block 7021 in the second direction +X. The post block 7022 may include a second molding portion 7422. The description of the second molding portion 1422 described with reference to FIGS. 1 to 19 may be applied identically to a description of the second molding portion 7422.

According to another example embodiment, the second structure 702 may include a filler 7023. The description of the filler 600 described with reference to FIGS. 1 to 19 may be applied identically to a description of the filler 7023. The filler 7023 may be positioned between the block 7021 and the post block 7022. A gap G1 may be formed between the block 7021 and the post block 7022, and the filler 7023 may fill the gap between the block 7021 and the post block 7022.

According to another example embodiment, the second structure 702 may include a boundary portion 7423. The description of the boundary portion 1423 described with reference to FIGS. 1 to 19 may be applied identically to a description of the boundary portion 7423. The boundary portion 7423 may be positioned between the block 7021 and the post block 7022. The boundary portion 7423 may be formed by the filler 7023 injected between the block 7021 and the post block 7022. The boundary portion 7423 may be a boundary wall positioned between the block 7021 and the post block 7022.

According to another example embodiment, the second structure 702 may include a second molding layer 742. The description of the second molding layer 142 described with reference to FIGS. 1 to 19 may be applied identically to a description of the second molding layer 742. The second molding layer 742 may include the first molding portion 7421, the second molding portion 7422, and the boundary portion 7423.

According to another example embodiment, a first degree of hardness of the first molding portion 7421 may be different from a second degree of hardness of the second molding portion 7422. A third degree of hardness of the boundary portion 7423 may be a value between the first degree of hardness and the second degree of hardness. The description of the relationship between the degrees of hardness of the first and second molding portions 1421, 1422 and the boundary portion 1423 described with reference to FIGS. 1 to 19 may be applied identically to a description of the degrees of hardness of the first and second molding portions 7421, 7422 and the boundary portion 7423.

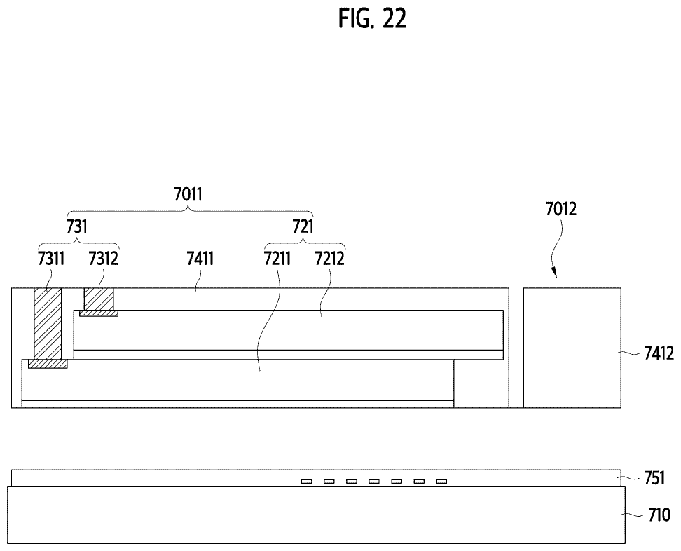

FIGS. 22 to 25 are diagrams illustrating a method of manufacturing the assembly 700 according to another example embodiment of the present disclosure.

Referring to FIG. 22, the method of manufacturing the assembly 700 may include an operation of positioning a block 7011 and a molding block 7012 over the carrier substrate 710. The block 7011 may have an identical structure to the block 7021 described with reference to FIG. 21. The block 7021 described with reference to FIG. 21 may refer to a block positioned in the second structure 702, and the block 7011 described with reference to FIG. 22 may refer to a block positioned in the first structure 701. However, the manufacturing processes and structures of the blocks 7011, 7021 described with reference to FIGS. 21 and 22 may be identical. The semiconductor package according to example embodiments of FIGS. 20 to 25 may be manufactured as the first structure 701 and the second structure 702, when the blocks 7011, 7021 positioned in both are assembled. The block 7011 positioned in the first structure 701 may be referred to as a “first block” and the block 7021 positioned in the second structure 702 may be referred to as a “second block.” Each of the first block 7011 and the second block 7021 may be manufactured by a method identical to the method of manufacturing the block 200 described with reference to FIGS. 3 to 7.

Referring to FIG. 22, the first block 7011 may include a first chip group 721. The description of the first chip group 121 described with reference to FIGS. 1 to 19 may be applied identically to a description of the first chip group 721. For example, the first chip group 721 may include a first-first chip 7211 and a first-second chip 7212 stacked on each other.

Referring to FIG. 22, the first block 7011 may include a first wiring post 731. The description of the first wiring post 131 described with reference to FIGS. 1 to 19 may be applied identically to a description of the first wiring post 731. For example, the first wiring post 731 may include a first-first wiring post 7311 connected to the first-first chip 7211 and a first-second wiring post 7312 connected to the first-second chip 7212.

Referring to FIG. 22, the molding block 7012 may be spaced apart from the first block 7011. The molding block 7012 may include a first-second molding portion 7412 spaced apart from a first-first molding portion 7411. The first-second molding portion 7412 may be stacked on a first redistribution layer 751.

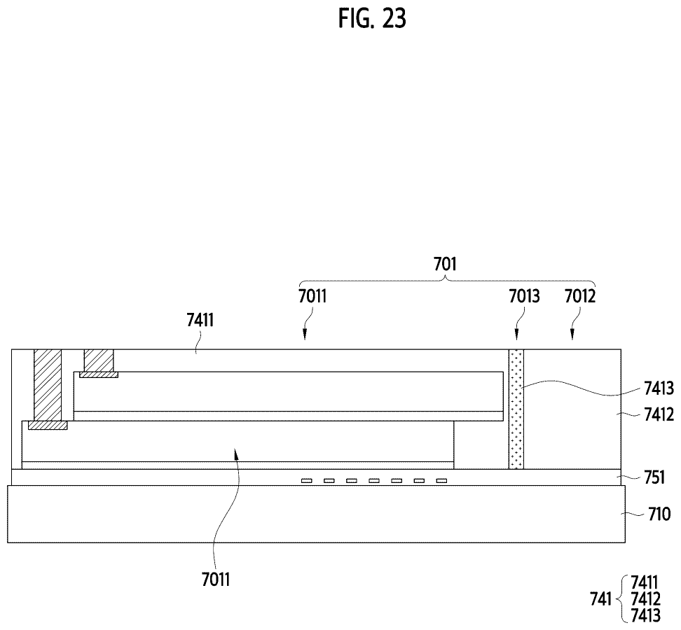

Referring to FIG. 23, the method of manufacturing the assembly 700 may include an operation of positioning a bonding filler 7013 between the first block 7011 and the molding block 7012. The bonding filler 7013 may be positioned between the first block 7011 and the molding block 7012 and in contact with each of the first block 7011 and the molding block 7012. The bonding filler 7013 may harden between the first block 7011 and the molding block 7012 and form a first-third molding portion 7413.

Referring to FIG. 23, the first structure 701 may include a first molding layer 741. The description of the first molding layer 141 described with reference to FIGS. 1 to 19 may be applied identically to a description of the first molding layer 741. The first molding layer 741 may include the first-first molding portion 7411, the first-second molding portion 7412, and the first-third molding portion 7413. A degree of hardness of the first-first molding portion 7411 may be different from a degree of hardness of the first-second molding portion 7412. A degree of hardness of the first-third molding portion 7413 may be a value between the degree of hardness of the first-first molding portion 7411 and the degree of hardness of the first-second molding portion 7412.

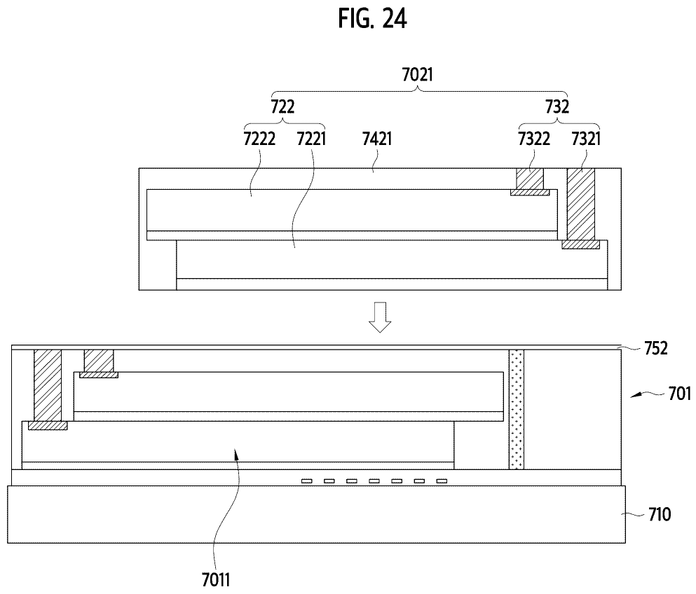

Referring to FIG. 24, the method of manufacturing the assembly 700 may include an operation of positioning the second block 7021 over the first structure 701. The second block 7021 may be stacked on a second redistribution layer 752 stacked with the first block 7011. The description of the second redistribution layer 152 described with reference to FIGS. 1 to 19 may be applied identically to a description of the second redistribution layer 752.

Referring to FIG. 24, the second block 7021 may include a second chip group 722. The description of the second chip group 122 described with reference to FIGS. 1 to 19 may be applied identically to a description of the second chip group 722. For example, the second chip group 722 may include a second-first chip 7221 and a second-second chip 7222 stacked on each other. The first molding portion 7421 may surround the second chip group 722.

Referring to FIG. 24, the second block 7021 may include a second wiring post 732. The description of the second wiring post 132 described with reference to FIGS. 1 to 19 may be applied identically to a description of the second wiring post 732. For example, the second wiring post 732 may include a second-first wiring post 7321 connected to the second-first chip 7221 and a second-second wiring post 7322 connected to the second-second chip 7222. The first molding portion 7421 may surround the second wiring post 732.

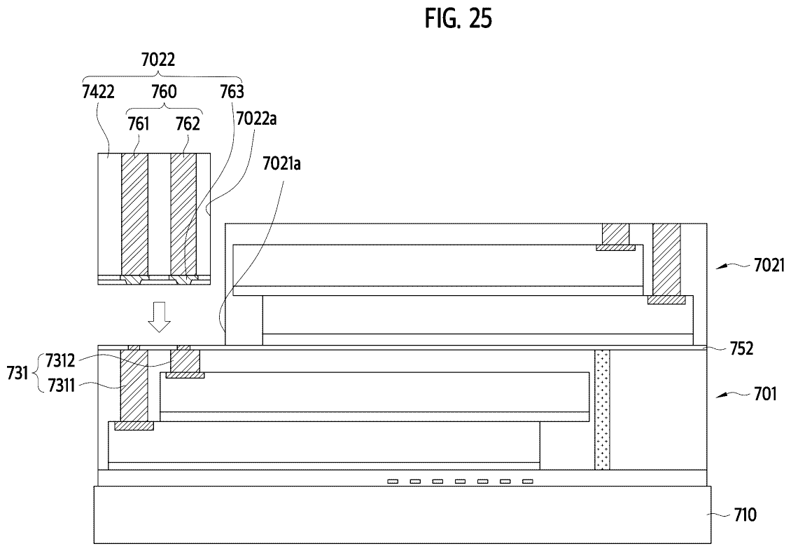

Referring to FIG. 25, the method of manufacturing the assembly 700 may include an operation of positioning the post block 7022. The description of the post blocks 300, 500 described with reference to FIGS. 1 to 19 may be applied identically to a description of the post block 7022. The post block 7022 may be positioned to be spaced apart from one side of the block 7021. A block surface 7021a of the block 7021 and a post block surface 7022a of the post block 7022 may be spaced apart from each other. A boundary portion (for example, the boundary portion 7423 of FIG. 21) may be positioned between the block 7021 and the post block 7022 and in contact with each of the block surface 7021a and the post block surface 7022a. The post block 7022 may be positioned over the first structure 701. The post block 7022 may be stacked on the second redistribution layer 752. The post block 7022 may be manufactured by a method identical to the method of manufacturing the post block 500 described with reference to FIGS. 13 to 16.

Referring to FIG. 25, the post block 7022 may include an extension post 760. The description of the extension post 160 described with reference to FIGS. 1 to 19 may be applied identically to a description of the extension post 760. For example, the extension post 760 may include a first extension post 761 electrically connected to the first-first wiring post 7311 and a second extension post 762 electrically connected to the first-second wiring post 7312. The post block 7022 may include an extension post pad 763. The description of the extension post pad 163 described with reference to FIGS. 1 to 19 may be applied identically to a description of the extension post pad 763. The extension post pad 763 may be connected to the second redistribution layer 752. The second molding portion 7422 may surround the extension post 760 and the extension post pad 763.

Referring to FIGS. 20 and 25, the assembly 700 manufactured by the method described with reference to FIGS. 22 to 25 may be stacked with the package substrate 10. The assembly 700 may be stacked on the package substrate 10 after the carrier substrate 710 is removed. The carrier substrate 710 may be a wafer or a panel provided to manufacture the assembly 700. The assembly 700 may be positioned for the second block 7021 to face the package substrate 10 and may be stacked on the package substrate 10.

According to example embodiments, it is possible to simplify a manufacturing process of a semiconductor package.

According to example embodiments, it is possible to suppress warpage in a semiconductor package.

While various example embodiments of the present disclosure are described in detail above, the scope of the present disclosure is not limited thereto, and it will be apparent to those of ordinary skill in the art that various modifications and variations may be made without departing from the technical idea of the present disclosure as defined by the appended claims. In addition, the aforementioned example embodiments may be implemented with some elements removed, and each example embodiment may be implemented in combination with each other.

What is claimed is:

1. A semiconductor package comprising:
a package substrate;
a first structure including a first chip on the package substrate, a first wiring post connected to the first chip, and a first molding layer surrounding the first chip and the first wiring post; and
a second structure including a second chip on the package substrate, a second wiring post connected to the second chip, and a second molding layer surrounding the second chip and the second wiring post,
wherein the second structure comprises:
a block in a portion of a first area overlapping the package substrate and including a first molding portion surrounding the second chip and the second wiring post;
a second molding portion in a second area adjacent the first area overlapping the package substrate; and
a boundary portion positioned between the second molding portion and a block surface located at a side of the first molding portion facing the second molding portion.

2. The semiconductor package of claim 1, further comprising an extension post positioned spaced apart from the block surface and surrounded by the second molding portion.

3. The semiconductor package of claim 1, further comprising a post block including the second molding portion and an extension post surrounded by the second molding portion,
wherein the boundary portion is in contact with each of the block surface and a post block surface facing in a direction toward the block surface of the post block.

4. The semiconductor package of claim 3, wherein the post block includes a plurality of post blocks arranged in a second direction perpendicular to a first direction in which the first structure and the block are stacked,
wherein each of the plurality of post blocks includes the post block surface, and
wherein one of the plurality of post blocks is in contact with the post block surface of another adjacent one of the plurality of post blocks.

5. The semiconductor package of claim 3, wherein the boundary portion is positioned between the block and the post block.

6. The semiconductor package of claim 3, wherein a first degree of hardness of the first molding portion included in the block and a second degree of hardness of the second molding portion included in the post block are different from each other, and a third degree of hardness of the boundary portion is a value between the first degree of hardness and the second degree of hardness.

7. The semiconductor package of claim 3, wherein the post block includes a post pad connecting the extension post and the first wiring post.

8. The semiconductor package of claim 1, further comprising a redistribution layer positioned between the first molding layer and the block,
wherein the block includes a block wiring layer stacked on the redistribution layer, electrically connected to the redistribution layer, and bonded to the first molding portion.

9. The semiconductor package of claim 8, wherein the redistribution layer includes:
a first wiring portion on which the block wiring layer is stacked; and
a second wiring portion spaced apart from the block wiring layer, and
wherein a step portion including an edge of the block wiring layer is formed in an area where the first wiring portion and the second wiring portion are connected.

10. The semiconductor package of claim 8, further comprising a post block including the second molding portion, an extension post surrounded by the second molding portion, and a post block wiring layer connected to the extension post, having a same thickness as the block wiring layer, and stacked on the redistribution layer.

11. A semiconductor package comprising:
a package substrate;
a first structure including a first chip on the package substrate, a first wiring post connected to the first chip, and a first molding layer surrounding the first chip and the first wiring post; and
a second structure including a second chip on the package substrate, a second wiring post connected to the second chip, and a second molding layer surrounding the second chip and the second wiring post,
wherein the second structure comprises:
a first molding portion comprising a first portion of the second molding layer, surrounding the second chip and the second wiring post, and having a first degree of hardness;
a second molding portion comprising a second portion separate from the first portion of the second molding layer and having a second degree of hardness different from the first degree of hardness; and
a boundary portion positioned between the first molding portion and the second molding portion, and having a third degree of hardness that is a value between the first degree of hardness and the second degree of hardness.

12. The semiconductor package of claim 11, further comprising a block including the first molding portion and a block surface spaced apart from the second molding portion,
wherein the boundary portion is in contact with the block surface between the block and the second molding portion.

13. The semiconductor package of claim 11, further comprising a post block including the second molding portion, an extension post surrounded by the second molding portion, and a post block surface spaced apart from a side of the first molding portion facing the post block surface,
wherein the boundary portion is located between the first molding portion and the post block.

14. The semiconductor package of claim 13, further comprising a block including the first molding portion and a block surface spaced apart from the second molding portion,
wherein the boundary portion is positioned between the block and the post block and in contact with each of the block surface and the post block surface.

15. The semiconductor package of claim 11, wherein the boundary portion includes a filler material in a space between the first molding portion and the second molding portion.

16. A method of manufacturing a semiconductor package, the method comprising:
stacking a plurality of chips spaced apart from each other on a base;
disposing a plurality of wiring posts corresponding to each of the plurality of chips;
forming a molding layer to surround the plurality of chips and the plurality of wiring posts;
cutting a block including at least one of the plurality of chips, at least one of the plurality of wiring posts, and at least a portion of the molding layer from the base; and
stacking the block overlapping a package substrate.

17. The method of claim 16, further comprising:
stacking the block and a first structure including a first chip stacked with a carrier substrate, a first wiring post connected to the first chip, and a first molding layer surrounding the first chip and the first wiring post.

18. The method of claim 16, further comprising:
cutting another portion of the molding layer and an extension post surrounded by the another portion to provide a post block; and
stacking the post block on the package substrate.

19. The method of claim 18, further comprising:
forming a boundary portion between the block and the post block.

20. The method of claim 16, further comprising:
stacking a molding block including another portion of the molding layer at a location spaced apart from the block.
